(19) United States
(12) Patent Application Publication
(10) Pub. No.: US 2007/0013013 A1
(43) Pub. Date: Jan. 18, 2007

(54) Semiconductor chemical sensor

(75) Inventors: Svetlana M. Zemskova, Edelstein, IL (US); Craig F. Habeger, Chillicothe, IL (US)

Correspondence Address: CATERPILLAR/FINNEGAN, HENDERSON, L.L.P., 901 New York Avenue, NW, WASHINGTON, DC, 20001-4413, US

(73) Assignee: Caterpillar Inc.

(21) Appl. No.: 11/180,887

(22) Filed: Jul. 14, 2005

(51) Int. Cl. H01L 29/82; H01L 27/14; H01L 29/84

(52) U.S. Cl. 257/414

(57) ABSTRACT

A chemical sensor is provided that includes a semiconductor layer, an organic chemical layer disposed on a surface of the semiconductor layer, and a heating element configured to heat the semiconductor layer.

### U.S. GOVERNMENT RIGHTS

This invention was made with government support under the terms of Subcontract No. 4000021385 awarded by the Department of Energy. The government may have certain rights in this invention.

### TECHNICAL FIELD

This disclosure pertains generally to chemical sensors, and more particularly, to functionalized semiconductor sensors.

### BACKGROUND

Chemical sensors have numerous uses. For example, some chemical sensors can rapidly and efficiently identify or measure environmental gases, facilitate medical diagnosis and monitoring, or detect hazardous conditions. In addition, some chemical sensors may be used to monitor reaction products, including certain engine exhaust gas emissions. Monitoring of engine exhaust gas emissions may allow improved control of machine operating parameters to provide decreased emissions of certain harmful chemicals or to improve machine performance.

Numerous types of chemical sensors are available. Such sensors may include, for example, functionalized electrical or optical materials. These functionalized materials have an organic dye layer disposed on the surface of an electrically or optically active material. The organic dye may be chosen to selectively interact with chemical species in the surrounding environment. Furthermore, interaction between these organic dyes and certain chemical species may produce measurable changes in the physical properties of the underlying electrically or optically active material.

One chemical sensor is disclosed in United States Patent Application Publication 2004/0072360, published in the name of Naaman on Apr. 15, 2005 (hereinafter the '360 publication). The '360 publication provides a semiconductor device for the detection of nitric oxide (NO). The device is composed of a layer of semiconducting material, at least one additional insulating or semiconducting layer, and a layer of multifunctional organic molecules capable of binding NO. The '360 publication further includes two pads making electrical contact with the semiconducting material layer.

While the device of the '360 publication may be useful for some applications, the device has several drawbacks. The device of the '360 publication is particularly described for use with biologic samples. Such samples will generally only be present in a controlled environment such as a lab, where environmental conditions such as temperature can be easily controlled. Furthermore, the device of the '360 publication includes no means for controlling device temperature when used in environments with relatively rapidly changing and hard to control environmental conditions, as may be present in engine exhaust streams. In addition, the device of the '360 publication may be difficult and expensive to produce.

The present disclosure is directed at overcoming one or more of the problems or disadvantages in the prior art chemical sensors.

### SUMMARY OF THE INVENTION

One aspect of the present disclosure includes a chemical sensor. The chemical sensor comprises a semiconductor layer, an organic chemical layer disposed on a surface of the semiconductor layer, and a heating element configured to heat the semiconductor layer.

A second aspect of the present disclosure includes a method for measuring a gas concentration. The method comprises selecting a chemical sensor including a semiconductor material and an organic chemical layer disposed on a surface of the semiconductor material, heating the semiconductor material to a predetermined temperature, and measuring the electrical conductivity of a region of the semiconductor layer that is in contact with the organic chemical layer.

A third aspect of the present disclosure includes an exhaust gas monitoring system. The system comprises a chemical sensor and a machine control unit. The chemical sensor includes a semiconductor layer, an organic chemical layer disposed on a surface of the semiconductor layer, and a heating element configured to heat the semiconductor layer. The machine control unit is configured to adjust one or more machine operating parameters based on a measurement from the chemical sensor.

### BRIEF DESCRIPTION OF THE DRAWINGS

FIG. 1 illustrates an exhaust system including an exhaust gas monitoring system, according to an exemplary disclosed embodiment.

FIG. 2A illustrates a perspective view of a chemical sensor, according to an exemplary disclosed embodiment.

FIG. 2B illustrates a cross-sectional view of a chemical sensor, according to an exemplary disclosed embodiment.

FIG. 3 illustrates a method of producing a chemical sensor, according to an exemplary disclosed embodiment.

### DETAILED DESCRIPTION

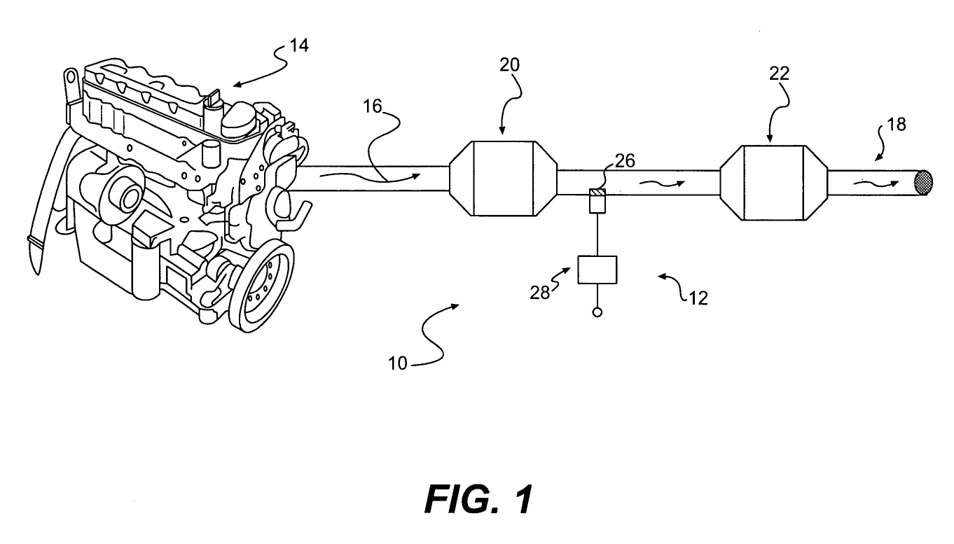

FIG. 1 illustrates an exhaust system 10 including an exhaust gas monitoring system 12, according to an exemplary disclosed embodiment. Exhaust system 10 includes an engine 14, which is configured to supply an exhaust gas stream 16 to an exhaust passage 18. Exhaust passage 18 may include a number of additional exhaust system components 20, 22, such as one or more catalysts, filters, exhaust system burners, oxygen sensors, additive supply systems, and any other suitable exhaust system component.

As shown, exhaust system 10 is an engine exhaust system as may be found in a diesel truck. However, exhaust system 10 may include any suitable exhaust system. For example, exhaust system 10 may include an engine exhaust system for any suitable work machine such as a crane, a dump truck, a bull-dozer, an ocean vessel, a generator set, or any other suitable machine. Further, exhaust system 10 may include an exhaust passage of any other industrial machine or operation including, for example, a factory, a fossil fuel burning power plant, a refinery, a chemical processing plant, or any other machine, facility, or operation in which it may be desirable to monitor and/or control the production of one or more chemical species.

Monitoring system 12 includes a chemical sensor 26 and one or more control units 28. Chemical sensor 26 may be configured to detect and/or measure the concentration of one or more chemical species contained within exhaust gas stream 16. Chemical sensor 26 can provide a signal indicative of the presence and/or concentration of measured chemicals to control unit 28. Control unit 28 may then adjust the operation of engine 14 or one or more exhaust system components 20, 22 based on measurements from chemical sensor 26.

Control unit 28 may include a variety of suitable control unit types. For example, control unit 28 may include an electronic engine control unit, which may be configured to adjust operational parameters of engine 14 in response to one or more environmental variables, including measurements from chemical sensor 26.

Control unit 28 and sensor 26 can be configured to measure and respond to a variety of chemical species in exhaust stream 16. For example, in some embodiments, chemical sensor 26 may be configured to detect or measure the concentration of one or more chemicals, such as ammonia, nitric oxide (NO), nitrogen dioxide, oxygen, sulfides, carbon monoxide, and/or any other suitable chemical, and control unit 28 may be configured to respond to concentration measurements for any chemical measured by sensor 26.

In some embodiments, control unit 28 may be configured to control exhaust emissions or machine performance. For example, in one embodiment, it may be desirable to control or minimize the release of NO or other chemicals from exhaust system 10. Control unit 28 may adjust the operational parameters of engine 14 or exhaust system 10 to control the production, elimination, and/or release of NO or other chemicals. In other embodiments, control unit 28 may control machine performance characteristics, which may be related to exhaust gas concentration. Such performance characteristics may include, for example, power output, fuel efficiency, temperature, noise level, vibration, or any other performance characteristic that may be related to exhaust gas chemical concentrations.

Control unit 28 may control exhaust gas concentration or performance characteristics by regulating a variety of different system variables. Such variables may include engine power output, air-to-fuel ratios, exhaust system additive concentrations, engine or exhaust temperature, exhaust gas pressure, and/or any other suitable factor.

As shown, sensor 26 is disposed downstream of engine 12 and between catalysts 20, 22. However, sensor 26 may be positioned at a variety of suitable exhaust passage locations, and multiple sensors 26 may be used. For example, in one embodiment sensor 26 may be positioned just downstream of engine 14, thereby allowing measurement of exhaust gas chemicals before any cleaning, catalysis, or other treatment has occurred. In another embodiment, sensor 26 may be positioned upstream or downstream of certain exhaust system components, thereby allowing monitoring of the effect of the selected exhaust system components on exhaust gas stream chemical concentrations. In still another embodiment, sensor 26 may be positioned near the end of exhaust passage 18, thereby allowing monitoring of environmental emissions of certain chemical species.

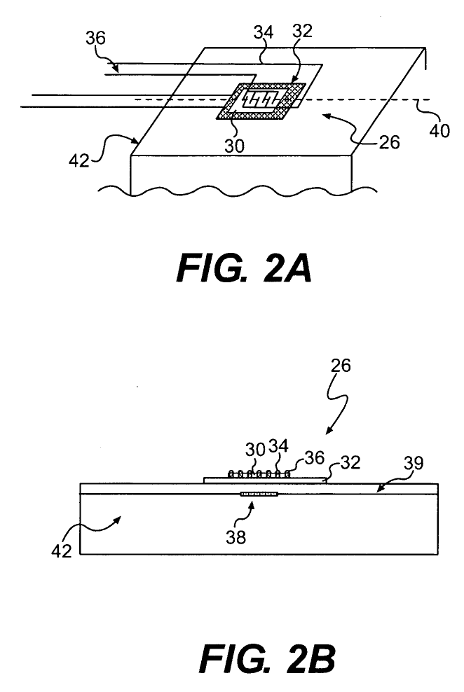

FIG. 2A illustrates a more detailed view of chemical sensor 26, according to an exemplary embodiment. As shown, chemical sensor 26 includes an organic chemical layer 30 disposed on a semiconductor layer 32. Two electrodes 34, 36 are placed in electrical contact with semiconductor layer 32 in the region of organic dye layer 30. A heating element 38 (as shown in FIG. 2B, which is a cross-sectional view of FIG. 2A at a line 40) may be configured to heat semiconductor layer 32, and the entire sensor 26 may be supported by an insulating substrate 42.

As shown in FIGS. 2A-2B, chemical sensor 26 includes a single sensor 26 disposed on insulating substrate 42. However, in some embodiments, chemical sensor 26 may include multiple sensors. For example, chemical sensor 26 may include an array of sensors 26, which may be disposed on a single substrate 42 or on multiple substrates 42. Furthermore, each sensor 26 in a sensor array may be configured to detect and/or measure one or more selected chemicals. In some embodiments, each sensor may be configured to measure a different chemical species. In other embodiments, two or more sensors 26 may be configured to measure the same chemical species, thereby providing redundancy in case one sensor should fail.

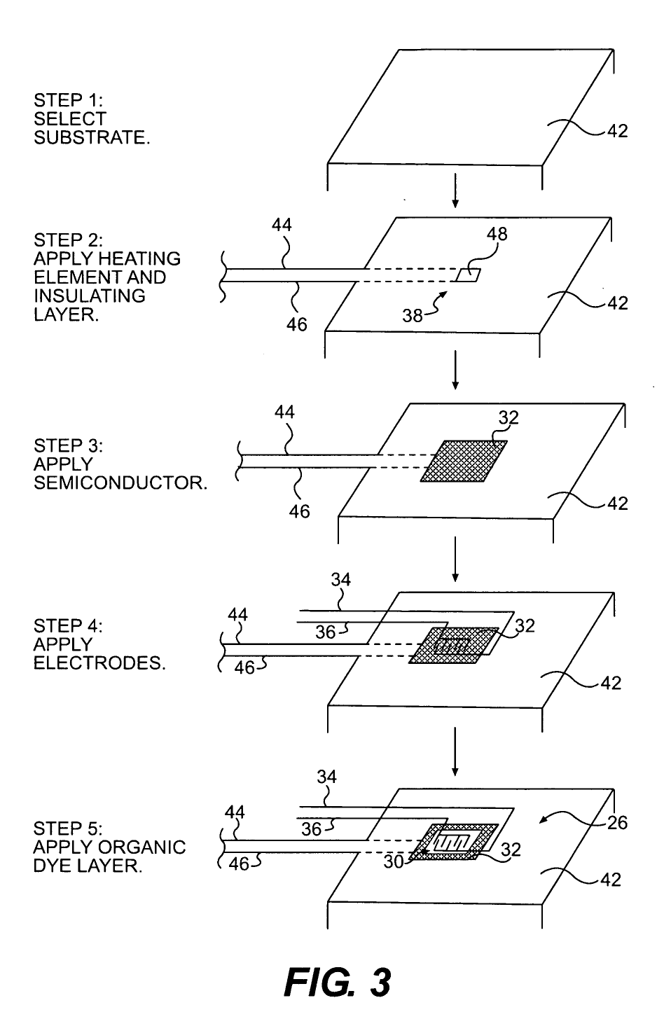

FIG. 3 illustrates a method for producing chemical sensor 26. As shown, the method includes selecting a suitable substrate material 42 (Step 1), applying a heating element 38 to substrate 42 (Step 2), applying semiconductor layer 32 to substrate 42 in the region of heating element 38 (Step 3), applying electrodes 34, 36 to semiconductor layer 32 (Step 4), and applying organic chemical layer 30 (Step 5).

Substrate material 42 may be selected from a variety of suitable substrates. For example, substrate material 42 may include a variety of suitable ceramic, glass, or polymeric materials. The specific substrate material 42 may be selected to provide adequate mechanical support to chemical sensor 26, to provide thermal and/or electrical insulation to semiconductor layer 30, and/or to bond with or adhere to components of chemical sensor 26, including semiconductor layer 32 and heating element 38. In one embodiment, substrate material 42 may include quartz.

Heating element 38 may be applied to substrate 42. In one embodiment, heating element 38 may include a resistive heating element, which may be configured to heat semiconductor layer 32. A suitable resistive heating element may include two or more heating element electrodes 44, 46 (as shown in FIG. 3), which will form an electrical connection with a main heating element body 48. Heating element electrodes 44, 46 will provide an electrical current to heating element body 48. The electrical current will provide resistive heating to heating element body 48 and semiconductor layer 32.

Heating element 38 (including heating element body 48 and electrodes 44, 46) may be electrically insulated from semiconductor layer 32. For example, in one embodiment, an insulating material 39 (as shown in FIG. 2B) may be applied over heating element 38. Insulating material 39 may include any suitable electrical insulator. In one embodiment, insulating material 39 may include the same material that is used to produce substrate 42. In one embodiment, insulating material 39 will include quartz. Electrical insulation of heating element 38 from semiconductor layer 32 will prevent the current flowing through heating element 38 from affecting measurements of sensor 26.

Heating element body 48 and heating element electrodes 44, 46 may be formed from a number of suitable materials. For example, heating element electrodes 44, 46 may be produced from any suitable conductive material, such as gold, copper, platinum, and/or any other conductor. In one embodiment, heating element body 48 may be produced from a conductor or semiconductor material, which may be heated by electrical current. For example, heating element body 48 may be produced from the same conductive material as heating element electrodes 44, 46 or from other materials. In one embodiment, heating element body 48 may be produced from a semiconductor material such as silicon, doped silicon, or any other suitable semiconductor.

Next, semiconductor layer 32 may be applied to substrate 42. In one embodiment, semiconductor layer 32 may be applied over heating element 38 or may be positioned proximate heating element 38 such that thermal energy from heating element 38 will be conducted to semiconductor layer 32.

Semiconductor layer 32 may include a number of suitable semiconductor materials or combinations of materials. For example, semiconductor layer 32 may include any Group IV, II-VI, IV-VI, or III-V semiconductor. Suitable Group IV semiconductors may include silicon, n-type silicon, and p-type silicon. Suitable IV-VI semiconductors may include, for example, tin oxide (SnO₂). Suitable II-VI semiconductors may include a Group II element, such as cadmium (Cd) and zinc (Zn), and a Group VI element, such as sulfur (S), selenium (Se), and tellurium (Te). Suitable III-V semiconductors may include a Group III element, such as gallium (Ga) and indium (In), and a Group V element such as arsenic (As) and phosphorus (P).

In one embodiment, semiconductor layer 32 may include a semiconductor material selected from transition metal sulfides, transition metal oxides, transition metal selenides, and transition metal tellurides. For example, suitable transition metal sulfides may include zinc sulfide (ZnS) and cadmium sulfide (CdS); suitable transition metal selenides may include zinc selenide (ZnSe) and cadmium selenide (CdSe); suitable transition metal tellurides may include zinc telluride (ZnTe) and cadmium telluride (CdTe), and suitable transition metal oxides may include zinc oxide (ZnO) and cadmium oxide (CdO).

Semiconductor layer 32 may be provided in a number of suitable forms. For example, in one embodiment, semiconductor layer 32 may be produced as a polycrystalline thin film. Such thin films may be produced using a variety of suitable processes. For example, a suitable semiconductor layer 32 may be produced using a number of different physical vapor deposition processes. In addition, suitable films may be produced by brushing or spraying a solution containing one or more semiconductor component elements onto substrate 42. The solution may then be dried to leave a suitable semiconductor thin film. Any suitable deposition process may be selected, and the specific deposition process may be selected based on cost, ease of use, reproducibility, and/or any other factor.

Electrodes 34, 36 may then be applied to semiconductor layer 32. Electrodes 34, 36 may form an electrical connection with semiconductor layer 32, and electrodes 34, 36 will be configured to measure an electrical property of semiconductor layer 32. In one embodiment, electrodes 34, 36 may be configured to measure the conductivity or resistivity of a region of semiconductor layer 38. Particularly, electrodes 34, 36 may be configured to measure the conductivity or resistivity of a section of semiconductor layer 32 that is covered with organic chemical layer 30.

Electrodes 34, 36 may be produced from a variety of suitable materials and with a number of configurations. For example, electrodes 34, 36 may be produced from any suitable conductor, such as gold, copper, platinum, and/or any other suitable conductive material. In addition, electrodes 34, 36 may be applied by connecting pre-formed electrodes 34, 36 to semiconductor layer 32. Alternatively, for smaller dimensions, electrodes 34, 36 may be produced using physical vapor deposition, photolithography, or any suitable electrical fabrication technique that may deposit electrode material directly onto semiconductor layer 38.

As shown, electrodes 34, 36 include a pair of interdigitated electrodes. However, any suitable electrode configuration may be selected. For example, electrodes 34, 36 may include a pair of planar electrodes, curved electrodes, or any other suitable electrode shape. The specific electrode configuration may be selected to provide sufficient surface area to measure the desired electrical property, to maximize measurement accuracy, or to minimize cost.

Organic chemical layer 30 may next be applied to semiconductor layer 38. As shown, organic chemical layer 30 is applied after producing electrodes 34, 36. However, in some embodiments, organic chemical layer 30 may be applied before or concurrently with electrodes 34, 36. Organic chemical layer 30 may be applied to a region of semiconductor layer 32 located between electrodes 34, 36, such that organic chemical layer 30 may affect an electrical property of semiconductor layer 32 between electrodes 34, 36.

Organic chemical layer 30 may include a variety of suitable chemicals, which may be chosen to selectively interact with one or more chemicals to be detected or measured. In addition, the specific chemicals may be chosen to interact with semiconductor layer 32 such that certain properties, including electrical or optical properties of semiconductor layer 32, will be affected by organic chemical layer 30. In one embodiment, organic chemical layer 30 may be configured to produce a change in an electrical property of semiconductor layer 32 based on the concentration of one or more exhaust gas chemicals.

In some embodiments, organic chemical layer 30 may include one or more organic dyes. Suitable dyes may include a variety of different porphyrins and/or phthalocyanines. The specific porphyrins and/or phthalocyanines may be selected based on a number of factors. For example, certain porphyrins and/or phthalocyanines may be chosen based on their selectively for chemical species to be measured, their ability to bind with semiconductor layer 32, their stability at elevated temperatures, their response to chemical species to be measured, cost, and any other suitable factor.

Some porphyrins and/or phthalocyanines may be selected to bind to semiconductor layer 32 without the need for certain binding moieties. For example, some porphyrins and/or phthalocyanines may bind to oxygen, sulfur, selenium, or tellurium atoms of transition metal oxides, selenides, sulfides, and tellurides. Therefore, in some embodiments, semiconductor layer 32 may include transition metal oxides, selenides, sulfides, and tellurides to facilitate binding of organic chemical layer 30 to semiconductor layer 32.

Suitable organic dyes may be selected based on their selective interaction with one or more chemicals to be measured by chemical sensor 26. In some embodiments, porphyrins and/or phthalocyanines having some degree of selective interaction with NO may be chosen. For example, ferriprotoporphyrin IX chloride (FePh), 5,10,15,20-tetraphenyl-21H,23H-porphine (TPP), and iron(II) phthalocyanine (FePc), which are shown below, may each provide suitable selectivity for NO.

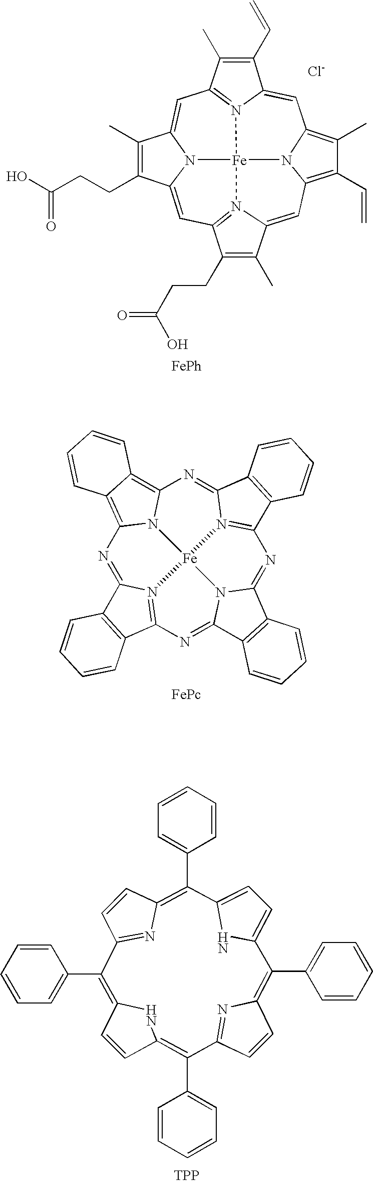

Alternatively, certain porphyrins and/or phthalocyanines having some degree of selective interaction with ammonia may be chosen. For example, 5,10,15,20-tetraphenyl-21H,23H-porphrine manganese(III) chloride (MnTPP) and Ni(II) octaethylporphine (NiOEP), which are shown below, can provide suitable selectivity for ammonia.

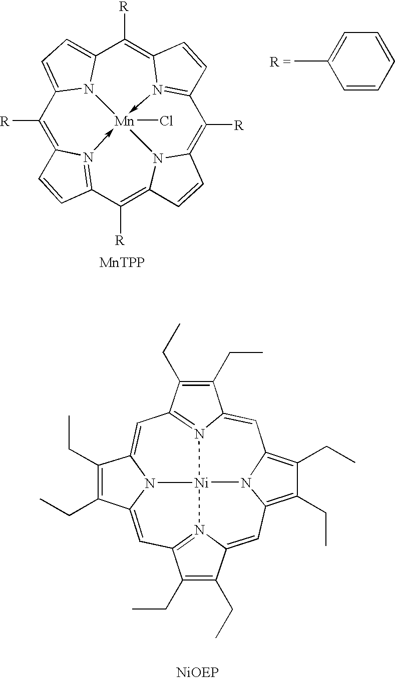

Further, some porphyrins and/or phthalocyanines having a certain selective interaction with nitrogen dioxide (NO₂) may be chosen. For example, lead(II) phthalocyanine (PbPc), which is shown below, can provide suitable selectivity for NO₂.

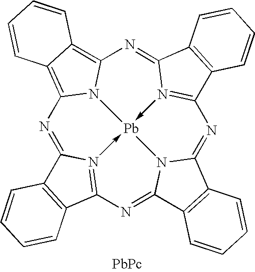

It should be noted that each of the porphyrins and phthalocyanines described may bind to some semiconductor materials without the need for additional binding moieties. For example, each of the porphyrins and phthalocyanines may bind to various transition metal sulfides, oxides, tellurides and selenides without the need for binding groups such as carboxyls, esters, or other binding groups. The binding mechanism may be largely dominated by an interaction between the porphyrin or phthalocyanine central core, which may include a metal such as iron or lead, and the sulfide, oxide, telluride, or selenide atoms of transition metal sulfides, oxides, tellurides, and selenides.

Organic chemical layer 30 may be produced using a number of suitable processes. For example, in one embodiment, organic chemical layer 30 may be produced using a solvent casting technique. Solvent casting can include dissolving one or more selected porphyrins or phthalocyanines in a solvent, such as ethanol. The solution can then be spread onto the region to be covered and dried in an inert gas. The process may be repeated until complete coverage is obtained or until a desired thickness is reached. For example, in some embodiments, the solvent casting process will be performed one time, between one and five times, or between one and ten times.

### EXAMPLE

### Production of a Nitric Oxide Sensitive Semiconductor

First, CdS thin film was produced on a quartz substrate. The quartz substrate was 10 mm×30 mm×3 mm, but any suitable size may be selected. Cadmium(II) N,N′diethyldithiocarbamate was dissolved in N,N′-dimethylformamide (1% by weight). The solution was sprayed onto a quartz substrate heated at 350° C. until dry to produce a thin film of CdS.

Next, iron protoporphyrin IX (FePh) was dissolved in 200 proof ethanol to produce a solution of approximately 10⁻⁵ molar FePh. Three drops were spread onto the CdS semiconductor to cover the entire semiconductor surface, and the material was dried under nitrogen flow. The process was repeated four more times to provide five layers of FePh. Deposition of fewer than five layers produced a discontinuous FePh layer, and greater than five layers produced solid agglomerates after evaporation of the solvent. Two more sensors were made by repeating the same process using 10⁻⁵ molar FePc and TPP.

The material described above may be used to measure exhaust gas concentrations. However, semiconductor properties, including semiconductor conductivity, may be strongly affected by temperature. Furthermore, exhaust gas temperatures may change relatively rapidly during machine use. Therefore, to accurately monitor chemical concentrations, it may be desirable to heat semiconductor layer 32 using heating element 38, as described previously.

Heating element 38 may be configured to heat semiconductor layer 32 to a predetermined temperature or temperature range. In some embodiments, heating element 38 may be configured to maintain the temperature of semiconductor layer 32 within a narrow temperature range, thereby reducing or minimizing measurement variations due to temperature fluctuations. For example, in some embodiments, heating element 38 may be configured to maintain the temperature of semiconductor layer 32 within about a 20 degree range, within about a 10 degree range, within about a 5 degree range, or within about a 1 degree range. Further, the maximum temperature may be selected based on the work machine exhaust gas temperature, the chemical sensor being used, sensor stability, or any other suitable factor. In some embodiments, the maximum temperature may be up to 500° C., up to 400° C., up to 300° C., or up to 200° C.

### INDUSTRIAL APPLICABILITY

The present disclosure provides a chemical sensor 26 for detecting and measuring the concentration of chemical species. The sensor 26 may be used anywhere it is desirable to monitor chemical concentrations.

The chemical sensor 26 of the present disclosure includes a functionalized semiconductor material having physical properties that are dependant upon the concentration of select chemical species. The functionalized semiconductor material includes a polycrystalline, thin-film semiconductor 32 that can be more easily produced and is less expensive than single-crystal semiconductor materials. The semiconductor material may include transitional metal oxides, selenides, sulfides, and/or tellurides, which can bind to a functional organic dye layer 30 without the need for additional chemical-binding moieties, and which is stable at elevated temperatures.

The chemical sensor 26 further includes a heating element 38, which can provide more accurate sensing with improved response times compared to sensors operated at ambient temperatures. Some environments, including exhaust gas passages, are subject to wide and rapid temperature fluctuations. These temperature fluctuations may greatly affect the calibration and/or accuracy of certain functionalized semiconductors. The chemical sensor 26 of the present disclosure, including the heating element 38, can be heated to a predetermined temperature range, thereby reducing measurement variations and calibration errors due to temperature fluctuations. In addition, semiconductor chemical sensors may have temperature-dependant response times, which are generally shorter at higher temperatures. Therefore, the heated sensor 26 of the present disclosure, may have a shorter response time than sensors operated at ambient temperatures. The shorter response time may provide more rapid and accurate measurements and improved control of engine operation.

It will be apparent to those skilled in the art that various modifications and variations can be made in the disclosed systems and methods without departing from the scope of the disclosure. Other embodiments of the disclosed systems and methods will be apparent to those skilled in the art from consideration of the specification and practice of the embodiments disclosed herein. It is intended that the specification and examples be considered as exemplary only, with a true scope of the disclosure being indicated by the following claims and their equivalents.

What is claimed is:

1. A chemical sensor, comprising:
a semiconductor layer;
an organic chemical layer disposed on a surface of the semiconductor layer; and
a heating element configured to heat the semiconductor layer.

2. The sensor of claim 1, wherein the heating element includes a resistive heating element.

3. The sensor of claim 1, wherein the heating element is configured to maintain the temperature of the at least one semiconductor layer within a predetermined range.

4. The sensor of claim 1, wherein the semiconductor layer includes a III-V semiconductor material.

5. The sensor of claim 4, wherein the III-V semiconductor includes gallium and at least one of arsenic and phosphorus.

6. The sensor of claim 1, wherein the semiconductor material includes a II-VI semiconductor material.

7. The sensor of claim 6, wherein the semiconductor includes at least one of cadmium and zinc.

8. The sensor of claim 7, further including at least one of sulfur, selenium, oxygen, and tellurium.

9. The sensor of claim 1, wherein the semiconductor material is selected from silicon, n-type silicon, and p-type silicon.

10. The sensor of claim 1, wherein the semiconductor layer includes a polycrystalline semiconductor.

11. The sensor of claim 1, wherein the semiconductor layer includes at least one of a transition metal sulfide, a transition metal oxide, a transition metal selenide, and a transition metal telluride.

12. The sensor of claim 1, wherein the one organic chemical layer includes a porphyrin.

13. The sensor of claim 12, wherein the porphyrin includes at least one of an iron protoporphyrin, a tetraphenyl porphine, and an octaethyl porphine.

14. The sensor of claim 1, wherein the one organic chemical layer includes a phthalocyanine.

15. The sensor of claim 14, wherein the phthalocyanine includes at least one of iron phthalocyanine and lead phthalocyanine

16. A method for measuring a gas concentration, comprising:
selecting a chemical sensor including a semiconductor material and an organic chemical layer disposed on a surface of the semiconductor material;
heating the semiconductor material to a predetermined temperature; and
measuring the electrical conductivity of a region of the semiconductor layer that is in contact with the organic chemical compound.

17. The method of claim 16, wherein the semiconductor material includes a polycrystalline semiconductor material.

18. The method of claim 16, wherein the semiconductor layer includes at least one of a transition metal sulfide, a transition metal oxide, a transition metal selenide, and a transition metal telluride.

19. The method of claim 16, wherein the organic chemical layer is applied using a solvent casting process.

20. The method of claim 19, wherein the solvent casting process is selected to apply between 1 and 6 layers of an organic chemical compound.

21. The method of claim 16, wherein the organic chemical layer includes a porphyrin.

22. The method of claim 21, wherein the porphyrin includes at least one of an iron protoporphyrin, a tetraphenyl porphine, and an octaethyl porphine.

23. The method of claim 22, wherein the at least one organic chemical layer includes a phthalocyanine.

24. The method of claim 23, wherein the phthalocyanine includes at least one of iron phthalocyanine and lead phthalocyanine.

25. An exhaust-gas monitoring system, including:
a chemical sensor, comprising:
a semiconductor layer;
an organic chemical layer disposed on a surface of the semiconductor layer; and
a heating element configured to heat the semiconductor layer; and
a machine control unit configured to adjust one or more machine operating parameters based on a measurement from the chemical sensor.

26. The system of claim 25, wherein the heating element is configured to maintain the temperature of the at least one semiconductor layer within a predetermined range.

27. The system of claim 25, wherein the semiconductor layer includes a polycrystalline semiconductor.

28. The system of claim 25, wherein the semiconductor layer includes at least one of a transition metal sulfide, a transition metal oxide, a transition metal selenide, and a transition metal telluride.

29. The system of claim 25, wherein the at least one organic chemical layer includes at least one of a porphyrin and a phthalocyanine.
